(19) United States
(12) Patent Application Publication
(10) Pub. No.: US 2019/0140676 A1
(43) Pub. Date: May 9, 2019

(54) SIGNAL RECEIVING APPARATUS AND SIGNAL PROCESSING METHOD THEREOF

(71) Applicant: MStar Semiconductor, Inc., Hsinchu Hsien (TW)

(72) Inventors: Chia-Wei CHEN, Hsinchu Hsien (TW); Kai-Wen CHENG, Hsinchu Hsien (TW); Ko-Yin LAI, Hsinchu Hsien (TW)

(21) Appl. No.: 15/866,587

(22) Filed: Jan. 10, 2018

(30) Foreign Application Priority Data
Nov. 9, 2017 (TW) 106138847

(51) Int. Cl. H04B 1/10; H04L 7/00; G06F 1/04; G06F 11/16; H03D 1/02

(52) U.S. Cl. CPC H04B 1/1027; H04L 7/0029; H03D 1/02; G06F 11/1604; G06F 1/04

(57) ABSTRACT

A signal processing apparatus includes an oscillation circuit, an interpolation circuit, a matching filter, a high-pass filter and a timing recovery circuit. The oscillation circuit generates a clock signal. The interpolation circuit performs interpolation on an input signal according to the clock signal to generate an interpolation sample result. The matching filter demodulates the interpolation sample result to generate an output signal. The high-pass filter performs high-pass filtering on the interpolation sample result to generate a filtered result. The timing recovery circuit receives the filtered result, and performs timing recovery according to the filtered result.

This application claims the benefit of Taiwan application Serial No. 106138847, filed Nov. 9, 2017, the subject matter of which is incorporated herein by reference.

### BACKGROUND OF THE INVENTION

### Field of the Invention

The invention relates to a signal receiving apparatus, and more particularly to a technique for enhancing performance of a timing recovery circuit in a signal processing apparatus.

### Description of the Related Art

With the advancement of electronics related technologies, various communication apparatuses have become popular. In many signal receiving apparatuses, before parsing data contents provided by a transmitting end, correct symbol timing needs to be first determined. More specifically, a timing recovery circuit in a signal receiving apparatus needs to determine an ideal sampling point applied to an input signal.

FIG. 1 shows function block diagram of a circuit associated with timing recovery in a Digital Video Broadcasting (DVB) receiving end. An input signal of an interpolation circuit 101 is a series of samples generated by a front-end circuit. The interpolation circuit 101 performs interpolation sampling on the input signal according to a clock signal provided by an oscillation circuit 102, and provides an interpolation sample result individually to a locking detection circuit 103 and a matching filter 104. The matching filter 104 demodulates the interpolation sample result, and an output signal thereof is transmitted to a subsequent circuit for further decoding. The locking detection circuit 103 determines, according to an eye diagram of the interpolation sample result, whether the timing of the receiving end is substantially synchronous with that of the transmitting end, i.e., whether a locked state is achieved. In other words, if an opening of the eye diagram of the interpolation sample result is large enough, it means that a difference between two sample points of a same symbol is greater than a predetermined value, and the signal quality is determined as being better. After locking, the subsequent circuit determines whether to adopt the output signal provided by the matching filter 104 according to contents of a locked signal outputted from the locking detection circuit 103.

In practice, in an environment with a larger amount of noise, an input signal is less stable, and a locking detection circuit 103 often takes a long period to determine that a receiving end has achieved a locked state, or sometimes cannot even determine a locked state.

### SUMMARY OF THE INVENTION

To resolve the above issues, the present invention provides a novel signal receiving apparatus and an associated signal processing method.

A signal receiving apparatus is provided according to an embodiment of the present invention. The signal processing apparatus includes an oscillation circuit, an interpolation circuit, a matching filter, a high-pass filter and a timing recovery circuit. The oscillation circuit generates a clock signal. The interpolation circuit performs interpolation on an input signal according to the clock signal to generate an interpolation sample result. The matching filter demodulates the interpolation sample result to generate an output signal. The high-pass filter performs high-pass filtering on the interpolation sample result to generate a filtered signal. The timing recovery circuit receives the filtered signal, and performs timing recovery according to the filtered signal.

A signal processing method for a signal receiving apparatus is further provided according to another embodiment of the present invention. The method includes: generating a clock signal; performing interpolation on an input signal according to the clock signal to generate an interpolation sample result; performing high-pass filtering on the interpolation sample result to generate a filtered result; and performing timing recovery according to the filtered signal. The method further includes: demodulating the interpolation sample result to generate an output signal.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 (prior art) is a function block diagram of a circuit associated with timing recovery in a Digital Video Broadcasting (DVB) receiving end;

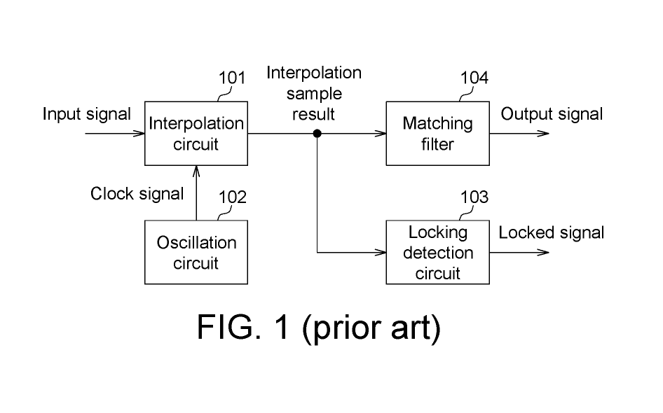

FIG. 2 is a function block diagram of a signal receiving apparatus according to an embodiment of the present invention;

FIG. 3 shows how a matching filter and a high-pass filter share a circuit according to an embodiment of the present invention; and

FIG. 4 is a flowchart of a signal processing method according to an embodiment of the present invention.

It should be noted that, the drawings of the present invention include functional block diagrams of multiple functional modules related to one another. These drawings are not detailed circuit diagrams, and connection lines therein are for indicating signal flows only. The interactions between the functional elements/or processes are not necessarily achieved through direct electrical connections. Further, functions of the individual elements are not necessarily distributed as depicted in the drawings, and separate blocks are not necessarily implemented by separate electronic elements.

### DETAILED DESCRIPTION OF THE INVENTION

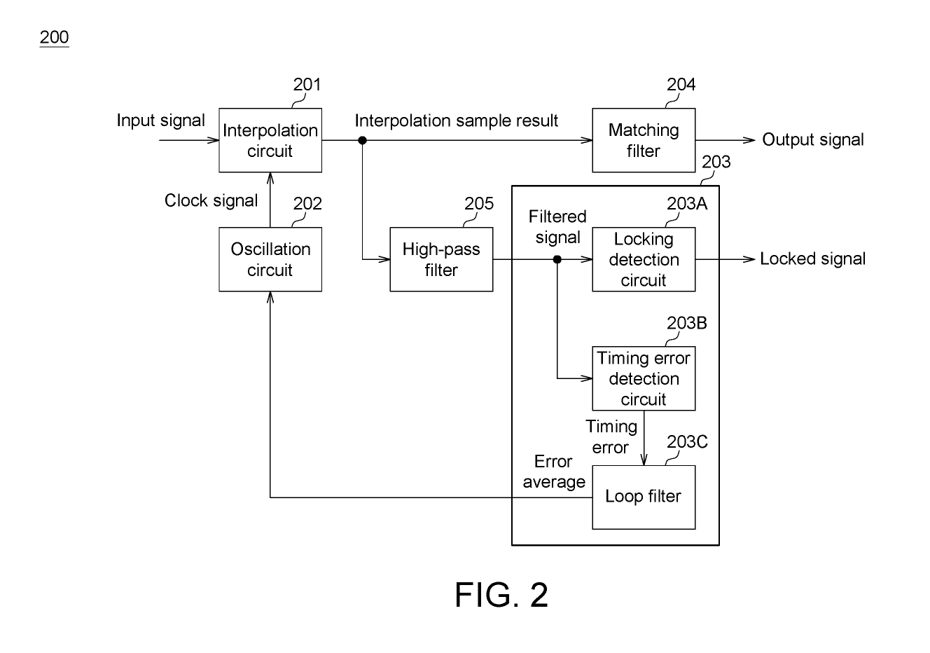

FIG. 2 shows a function block diagram of a signal processing apparatus according to an embodiment of the present invention. In practice, a signal processing apparatus 200 may be integrated into various communication systems, e.g., a Digital Video Broadcasting (DVB) receiver, that need to perform timing recovery according to an interpolation sample result of a received signal. As shown in FIG. 2, the signal receiving apparatus 200 includes an interpolation circuit 201, an oscillation circuit 202, a timing recovery circuit 203, a matching filter 204 and a high-pass filter 205. Functions of the circuits are given in detail below.

The interpolation circuit 201 performs interpolation on an input signal according to a clock signal generated by the oscillation circuit 202 to generate an interpolation sample result. The interpolation sample result is provided individually to the matching filter 204 and the high-pass filter 205. The matching filter 204 demodulates the interpolation sample result, and an output signal thereof is transmitted to a subsequent circuit for further decoding. The high-pass filter 205 performs high-pass filtering on the interpolation sample result to generate a filtered result.

The timing recovery circuit 203 receives the filtered signal, and performs timing recovery according to the filtered signal. The timing recovery circuit 203 includes a locking detection circuit 203A, a timing error detection circuit 203B and a loop filter 203C. The locking detection circuit 203A determines whether the receiving end has reached a locked state according to the filtered signal. The timing error detection circuit 203B performs timing error detection on the filtered signal to generate a set of timing errors. The loop filter 203C generates an error average of the set of timing errors for the oscillation circuit 202 to correct the phase and/or the frequency of the clock signal thereof. A lower error average indicates that a sampling point selected by the interpolation circuit 201 has higher accuracy, and the interpolation sample result outputted is closer to being ideal.

It should be noted that, information that the locking detection circuit 203A and the timing error detection circuit 203B need for respective detection operations is mainly associated with state transition of a signal (e.g., a signal falling edge from a high potential level to a low potential level, or a signal rising edge from a low potential level to a high potential level), and such information associated with these transition points is included in a high-frequency range in the frequency domain. Thus, by selecting an appropriate cut-off frequency band for the high-pass filter 205, information that is needed for the detection performed by the locking detection circuit 203A and the timing error detection circuit 203B can be preserved. Compared to the interpolation sample result outputted by the interpolation circuit 201, the filtered signal in overall has a smaller amount of noise and is more stable. Using the filtered signal as a detection target allows the locking detection circuit 203A to quickly determine a locked state. Further, using the filtered signal as a detection target enables the timing error detection circuit 203B to determine a reliable timing error, and thus the time that the interpolation circuit 201 identifies an ideal sampling time point is reduced. In an environment with a large amount of noise, the effectiveness of enhancing signal quality of the timing recovery circuit 203 by means of the high-pass filter 205 is particularly significant.

In practice, the cut-off frequency band of the high-pass filter 205 can be determined according to a frequency band distribution of the interpolation sample result, and is not limited to a specific value, and the associated circuit is not limited to a specific structure.

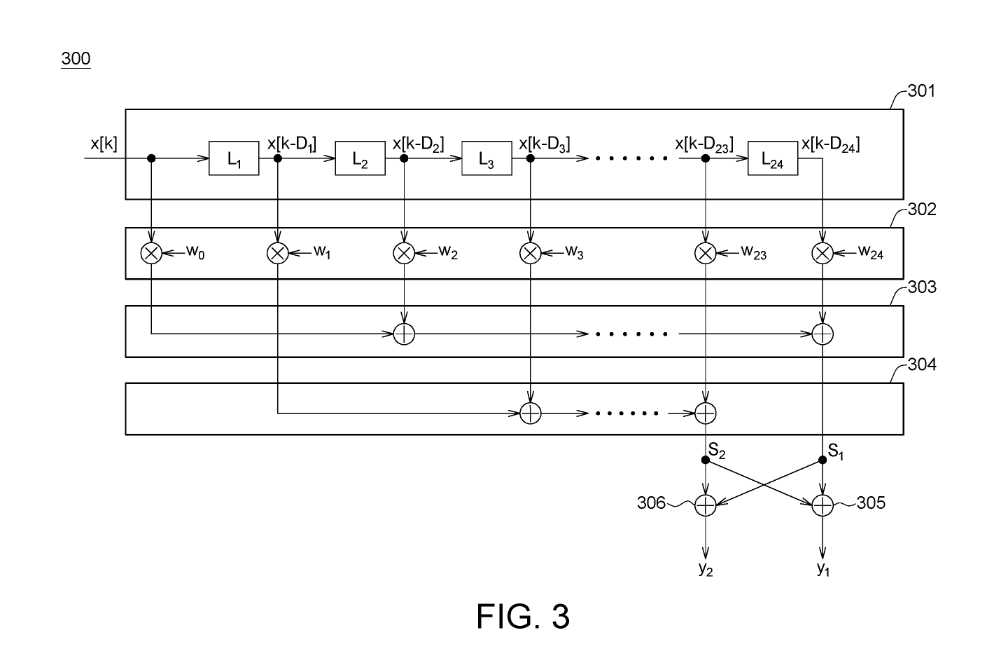

To save hardware resources and power consumption, the high-pass filter 205 may be designed to share a part of a circuit with the matching filter 204. FIG. 3 shows an example of a filter circuit 300 having functions of both high-pass filtering and matching filtering. The filter circuit 300 includes a delay circuit 301, a multiplication circuit 302, a first addition circuit 303, a second addition circuit 304, a third addition circuit 305 and a subtraction circuit 306. The delay circuit 301 includes N number of delay elements L connected in series (where N is a positive integer greater than 1), and generates N number of delayed signals for an interpolation sample result x[k]. In FIG. 3, N is equal to 24 in the delay circuit 300 for example. If the symbol i represents an integer index in a range between 1 and (N−1), a delay amount D₍ᵢ₊₁₎ corresponding to an (i+1)^{th} delayed signal is greater than a delay amount Dᵢ corresponding to an i^{th} delayed signal. The multiplication circuit 302 multiples the i^{th} delayed signal by an i^{th} weight to generate an i^{th} weighted result. In practice, the delay amounts and weights are designed to match implementing the function of the matching filter 204. The first addition circuit 304 sums up the interpolation sample result x[k] and twelve delayed signals with the integer index i in even numbers to generate a first summation value S₁. The second addition circuit 304 sums up the other twelve delayed signals with the integer index i in odd numbers to generate a first summation value S₂. The third addition circuit 305 adds the first summation value S₁ and the second summation value S₂ to provide an addition result y₁, as the matching filter result, i.e., the output of the matching filter 204. The subtraction circuit 306 subtracts the second summation value S₂ from the first summation value S₁ to provide a difference y₂, which is a high-pass filtered result, i.e., the output of the high-pass filter 205. One person skilled in the art can understand that, there are various circuit configurations and elements capable of implementing the above concepts without departing from the spirit of the present invention.

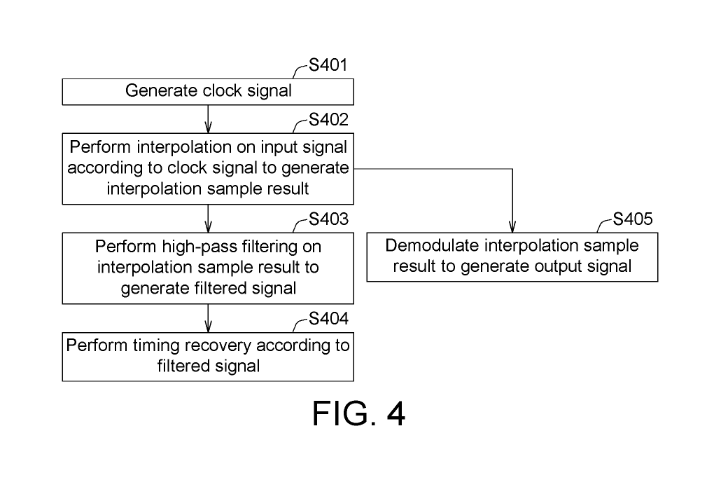

FIG. 4 shows a flowchart of a signal processing method for a signal receiving apparatus according to another embodiment of the present invention. In step S401, a clock signal is generated. In step S402, interpolation is performed on an input signal according to the clock signal to generate an interpolation sample result. In step S403, high-pass filtering is performed on the interpolation sample result to generate a filtered signal. In step S404, timing recovery is performed according to the filtered signal. Before step S403, the signal processing method further includes step S405, in which the interpolation sample result is demodulated to generate an output signal. One person skilled in the art can understand that, operation variations in the description associated with the signal receiving apparatus 200 can be applied to the signal processing method in FIG. 4, and shall be omitted herein.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A signal receiving apparatus, comprising:
an oscillation circuit, generating a clock signal;
an interpolation circuit, performing interpolation on an input signal according to the clock signal to generate an interpolation sample result;
a matching filter, demodulating the interpolation sample result to generate an output signal;
a high-pass filter, performing high-pass filtering on the interpolation sample result to generate a filtered signal; and
a timing recovering circuit, receiving the filtered signal, and performing timing recovery according to the filtered signal,
wherein the high-pass filter is implemented to share a part of a circuit with the matching filter, and
wherein the matching filter and the high-pass filter comprise:
a delay circuit, generating N number of delayed signals for the interpolation sample result, wherein a delay amount corresponding to an (i+1)^{th} delayed signal is greater than a delay amount corresponding to an i^{th} delayed signal, i is an integer index between 1 and (N−1), and N is an integer greater than 1;
a multiplication circuit, multiplying the i^{th} delayed signal by an i^{th} weight to generate an i^{th} weighted result;
a first addition circuit, summing up the interpolation sample result and the delayed signals having the integer index i in even numbers to generate a first summation value;
a second addition circuit, summing up the delayed signals having the integer index i in odd numbers to generate a second summation value;
a third addition circuit, adding the first summation value and the second summation value to generate the output signal; and
a subtraction circuit, subtracting the second summation value from the first summation value to generate the filtered signal.

2. The signal receiving apparatus according to claim 1, wherein the timing recovery circuit comprises:
a timing error detection circuit, performing timing error detection on the filtered signal to generate a set of timing errors; and
a loop filter, generating an error average of the set of timing errors for the oscillation circuit to correct the clock signal.

3. The signal receiving apparatus according to claim 1, wherein the timing recovery circuit comprises:
a locking detection circuit, determining, according to the filtered signal, whether the signal receiving apparatus has reached a locked state.

4-5. (canceled)

6. A signal processing method, applied to a signal receiving apparatus, comprising:
generating a clock signal;
performing interpolation on an input signal according to the clock signal to generate an interpolation sample result;
demodulating the interpolation sample result to generate an output signal;
performing high-pass filtering on the interpolation sample signal to generate a filtered signal; and
performing timing recovery according to the filtered signal,
wherein a high-pass filter used to perform the high-pass filtering is implemented to share a part of a circuit with a matching filter used to perform the demodulating the interpolation sample result,
wherein the matching filter and the high-pass filter are configured to perform the steps of:
generating N number of delayed signals for the interpolation sample result, wherein a delay amount corresponding to an (i+1)^{th} delayed signal is greater than a delay amount corresponding to an i^{th} delayed signal, i is an integer index between 1 and (N−1), and N is an integer greater than 1;
multiplying the i^{th} delayed signal by an i^{th} weight to generate an i^{th} weighted result;
summing up the interpolation sample result and the delayed signals having the integer index i in even numbers to generate a first summation value;
summing up the delayed signals having the integer index i in odd numbers to generate a second summation value;
adding the first summation value and the second summation value to generate the output signal; and
subtracting the second summation value from the first summation value to generate the filtered signal.

7. The signal processing method according to claim 6, wherein the timing recovery comprises:
performing timing error detection on the filtered signal to generate a set of timing errors; and
generating an average value of the set of timing errors to correct the clock signal.

8. The signal processing method according to claim 6, wherein the timing recovery comprises:
determining, according to the filtered signal, whether the signal receiving apparatus has reached a locked state.
